(19) United States
(12) Patent Application Publication
(10) Pub. No.: US 2026/0319048 A1
(43) Pub. Date: Oct. 15, 2026

(54) METHODS AND APPARATUS FOR MAGNETIC RESONANCE DIFFUSION METAL ARTIFACT CORRECTION (DMAC) IMAGING

(71) Applicant: Thomas Jefferson University, Philadelphia, PA (US)

(72) Inventors: Slimane Tounekti, Ardmore, PA (US); Devon M Middleton, Philadelphia, PA (US); Feroze B. Mohamed, Philadelphia, PA (US); Mahdi Alizadeh, Philadelphia, PA (US)

(21) Appl. No.: 19/473,957

(22) PCT Filed: Apr. 10, 2024
(86) PCT No.: PCT/US2024/023891

§ 371 Date: Oct. 9, 2025

Related U.S. Application Data
(60) Provisional application No. 63/458,308, filed on Apr. 10, 2023.

(51) Int. Cl. G01R 33/563; G01R 33/483; G01R 33/56; G01R 33/561; G01R 33/565

(52) U.S. Cl. CPC G01R 33/56341; G01R 33/4835; G01R 33/5607; G01R 33/5616; G01R 33/56536

(57) ABSTRACT

A method of a sampling scheme for magnetic resonance diffusion metal artifact correction (DMAC) imaging includes identifying a region of interest of a body part of a human, the method further includes generating a plurality of readout trains using a plurality of radiofrequency pulses to excite the region of interest and produce a plurality of magnetic resonance imaging (MRI) signals. Each radiofrequency pulse from the plurality of radiofrequency pulses is configured to traverse along the same readout encoding (RE) direction in parallel. The method further includes applying a plurality of diffusion encoding parameters on the plurality of MRI signals. The method further includes generating, based on the plurality of diffusion encoding parameters, a reconstructed image of the region of interest that includes a reduced field of view (rFOV) along the phase encoding (PE) direction. The reconstructed image includes a high resolution and distortion reduced image of the region of interest.

### CROSS-REFERENCE TO RELATED APPLICATION(S)

This application claims the benefit of priority to U.S. Provisional Patent Application Ser. No. 63/458,308 entitled “MAGNETIC RESONANCE DIFFUSION METAL ARTIFACT CORRECTION (DMAC) IMAGING METHOD,” filed Apr. 10, 2023, the disclosure of which is incorporated herein by reference in its entirety

### STATEMENT REGARDING FEDERALLY SPONSORED RESEARCH OR DEVELOPMENT

This invention was made with government support under Contract No. R01NS111113 awarded by the National Institute of Neurological Disorders and Stroke (NINDS) of the National Institutes of Health (NIH). The government has certain rights in the invention.

### BACKGROUND OF THE INVENTION

Diffusion Tensor Imaging (DTI) has been emerged as key tool for in-vivo investigation of the central nervous system (i.e., brain and spinal cord (SC)) integrity and white matter (WM) connectivity mapping. It has the potential of probing changes in neural system microstructure with certain pathology by assessing the diffusion properties of water molecules inside the biological tissues in multiple directions, providing insights into the organization and orientation of structures. DTI-derived metrics, i.e., Fractional Anisotropy (FA), Mean Diffusivity (MD), Radial Diffusivity (RD), and Axial Diffusivity (AD), could be computed and used as a reliable imaging biomarker for describing the SC microstructure changes with certain pathology.

Spinal Cord disorders such as spinal cord injury (SCI) and Degenerative Spondylotic Myelopathy (DSM) can affect the entire nervous system and lead to tissue/axonal damage, i.e., demyelination, transection, and atrophy, resulting in serious clinical complication including motor and/or sensory systems dysfunction, partial or complete paralysis, etc. In this context, the microstructural damages such as demyelination and axonal loss associated with SCI cause changes in the diffusivity of water in the spinal cord, and fiber bundles density, exhibiting changes in DTI-derived metrics according to the level and severity of the damage. Surgical intervention for SCI treatment can entail implantation of metallic hardware (Anterior or Posterior) for maintaining SC stabilization and avoid further short-term or long-term complications.

Structural MRI techniques, i.e., T1- and T2-weighted imaging, and DTI have gained popularity in clinical practice compared to conventional radiology modalities (CT, X-Ray) for preoperative diagnosis and assess of SCI. Some studies has shown that the change of DTI-metrics correlates with the change in the mJOA score as well as with the mJOA recovery rate, showing evidence that preoperative DTI has prognostic potential in predicting surgical outcomes. However, DTI is hampered by its intrinsic low-sensitivity, as well as the low-spatial resolution and high-sensitivity to motion, leading to image distortions and a weak signal-to-noise ratio (SNR). In addition, performing DTI on SC can be technically challenging mainly due to the small dimensions of the SC, the physiological motion (e.g., heart, lungs, and throat in its proximity) and the susceptibility-induced distortions. However, some developments in newer pulse sequences coupled with spine specific post processing capabilities have overcome these barriers enabling reproducible and reliable data collection of the human spinal cord. For example, DTI is often performed using the single-shot Echo Planar Imaging pulse sequence (SS-EPI) due to its fast acquisition speed. However, this acquisition method can be prone to various limitations, including eddy-currents and high-sensitivity to magnetic field inhomogeneity, inducing artifacts dramatically affecting the image quality. To address some of these technical issues, two dimension radiofrequency (2DRF) pulses have been introduced and coupled with the SS-EPI readout for collecting reduced Field-Of-View (rFOV) dMRI data of the SC. The rFOV-SS-EPI acquisition technique has been shown to provide high resolution, reduced-distortion dMRI of SC and has been implemented on most vendors' MR scanners. In addition, Phase-segmented EPI (PS-EPI) and readout-segmented EPI (RS-EPI) pulse sequences have been introduced recently for performing high-resolution and distortion reduced DTI on the brain. However, the application of these techniques for SC diffusion imaging remains limited due to their high sensitivity to motion.

Given these technical challenges limiting the ability of collecting images near the metal hardware, the use of DTI for evaluating post-operative clinical outcomes remain an unexplored field and the post-surgery SCI assessment is still heavily based on structural MRI techniques and a surgeon's skills. Studies have attempted various acquisition approaches to demonstrate the feasibility of performing metal-artifacts reduction for DTI scan near metal implant [21-23].

Even with all these new improvements, the postsurgical metallic implants typically induce dramatic magnetic field inhomogeneities, leading to severe image distortions. Postsurgical metallic implants typically induce dramatic magnetic field inhomogeneities, leading to severe image distortions. The metal-induced artifact depends on the implant hardware (material, size, shape), the magnetic field BO strength, and MRI sequence. The metal-induced artifact depends on the implant hardware (material, size, shape), the magnetic field BO strength, and MRI sequence. Moreover, DTI can often be performed using the single-shot Echo Planar Imaging pulse sequence (SS-EPI) due to its fast acquisition speed. However, this acquisition method can be prone to various limitations, including Eddy-current and high-sensitivity to magnetic field inhomogeneity, inducing artifacts dramatically affecting the image quality. Phase-segmented EPI (PS-EPI) and readout-segmented EPI (RS-EPI) pulse sequences have been introduced recently for performing high-resolution and distortion reduced DTI on Brain. Though, the application of these techniques for SC diffusion imaging remains limited due to their high sensitivity to motion.

Some studies have attempted various acquisition approaches to demonstrate the feasibility of performing metal-artifacts reduction for DTI scan SC near metal implant. Despite these recent technical developments, the potential of effectively suppress metal-induced artifacts for the diffusion-MRI scan is still unreached. This is mainly due to the limitations of the proposed techniques, including through-plane distortion, image blurring, and low-SNR. In addition, this can be due to the high BO field inhomogeneity in proximity to the metal, specifically at ultra-high field (UHF) such as 3 Tesla (3 T) or 7 T. Therefore, given the technical challenges that limit the potential of getting images near the metal hardware, a need exists for the use of DTI for evaluating postoperative clinical outcomes as the post-surgery SCI assessment can still be heavily based on structural MRI techniques and a surgeon's skills.

### BRIEF DESCRIPTION OF THE DRAWINGS

For a fuller understanding of the nature and desired objects of the present invention, reference is made to the following detailed description taken in conjunction with the accompanying drawing figures wherein like reference characters denote corresponding parts throughout the several views.

FIG. 1 is a diagrammatic illustration of a cervical spine phantom used for demonstrating magnetic resonance diffusion metal artifact correction (DMAC) imaging, according to some embodiments.

FIG. 2 is an illustrative representation of a readout sampling scheme of the single-shot EPI (SS-EPI), Phase-Segmented EPI (PS-EPI), and the Readout-Segmented EPI (PS-EPI), according to some embodiments.

FIG. 3 is an illustrative representation of a developed rFOV-PS-EPI pulse sequence, according to some embodiments.

FIG. 4 is diagrammatic illustration of the b0-images and the trace maps obtained using the standard SS-EPI, the PS-EPI, the RS-EPI, rFOV-SS-EPI and the developed rFOV-PS-EPI pulse sequence of the same slice, according to some embodiments.

FIG. 5 is a diagrammatic illustration of axial views of the b0-images and MD maps obtained at 0 mm, 5 mm, 10, 15, 20 mm from the metal using the rFOV-PS-EPI and rFOV-SS-EPI pulse sequences, according to some embodiments.

FIG. 6 is a diagrammatic illustration displaying the effects of long echo train EPI readout on the image distortions, according to some embodiments.

FIG. 7 is an illustrative representation of ROI-based signal void area measurement at the sagittal view of the b0-images acquired with the rFOV-SS-EPI and the rFOV-PS-EPI, according to some embodiments.

FIG. 8 is a diagrammatic illustration of an image-wise comparison between the two pulse sequences, according to some embodiments.

FIG. 9 is an illustrative representation of fractional anisotropy (FA) map overlays on T2-weighted image in an SCI subject using the conventional rFOV-SS-EPI sequence, according to some embodiments.

FIG. 10 is a graphical illustration of the spin-echo multi-shot EPI sequence with the Gradient Echo (GE)-based reference ACS for phase inconsistency correction, according to some embodiments.

FIG. 11 is a flow diagram of a method for magnetic resonance diffusion metal artifact correction (DMAC) imaging, according to some embodiments.

### DEFINITIONS

The instant invention is most clearly understood with reference to the following definitions.

As used herein, the singular form “a,” “an,” and “the” include plural references unless the context clearly dictates otherwise.

Unless specifically stated or obvious from context, as used herein, the term “about” is understood as within a range of normal tolerance in the art, for example within 2 standard deviations of the mean. “About” can be understood as within 10%, 9%, 8%, 7%, 6%, 5%, 4%, 3%, 2%, 1%, 0.5%, 0.1%, 0.05%, or 0.01% of the stated value. Unless otherwise clear from context, all numerical values provided herein are modified by the term about.

As used in the specification and claims, the terms “comprises,” “comprising,” “containing,” “having,” and the like can have the meaning ascribed to them in U.S. patent law and can mean “includes,” “including,” and the like.

Unless specifically stated or obvious from context, the term “or,” as used herein, is understood to be inclusive.

The terms “proximal” and “distal” can refer to the position of a portion of a device relative to the remainder of the device or the opposing end as it appears in the drawing. The proximal end can be used to refer to the end manipulated by the user. The distal end can be used to refer to the end of the device that is inserted and advanced and is furthest away from the user. As will be appreciated by those skilled in the art, the use of proximal and distal could change in another context, e.g., the anatomical context in which proximal and distal use the patient as reference, or where the entry point is distal from the user.

Ranges provided herein are understood to be shorthand for all of the values within the range. For example, a range of 1 to 50 is understood to include any number, combination of numbers, or sub-range from the group consisting 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, or 50 (as well as fractions thereof unless the context clearly dictates otherwise).

### DETAILED DESCRIPTION OF THE INVENTION

Provided herein is a method for magnetic resonance diffusion metal artifact correction (DMAC) imaging or a correction and/or a reduced-Field-Of-View phase-segmented EPI (rFOV-PS-EPI) diffusion weighted MR pulse sequence for addressing the geometric distortions near the metal in DTI scan of SC at 3 T. Provided herein, the rFOV technique is combined with the PS-EPI pulse sequence, so called (rFOV-PS-EPI), to address geometric distortions near the metal in DTI scan of SC at 3 T. High-resolution distortion reduced diffusion-weighted images can be collected on a custom-build cervical spine phantom model with metallic implant. The efficacy of the pulse sequence in reduction of metal-artifacts can be evaluated through the comparison with the rFOV-SS-EPI pulse sequence as well as the full-FOV approaches: SS-EPI, PS-EPI, and RS-EPI.

In some embodiments, the developed pulse sequence is based on the combination of the reduced Field-Of-View (rFOV) strategy and multi-shot EPI, termed rFOV-MS-EPI. DTI data collected using: the rFOV-MS-EPI and the single-shot EPI (rFOV-SS-EPI) typically used for SC (spinal cord) scan. Geometric distortion and signal void can be assessed to evaluate images and compare the two sequences on a custom-built phantom based on a cervical spine model with metal implants. In some implementations, asparagus n be used in the phantom as representative of the SC. In phantom model slice-by-slice ROIs can manually selected following the asparagus edge on T2-W image and the ADC maps computed from the rFOV-MS-EPI, rFOV-SS-EPI. Circularity and Eccentricity parameters can then be extracted and used for pairwise comparison between the structural and diffusion data. For example, a two-sample t-test was performed with p-value of 0.05 or less to indicate statistical significance.

In some implementations, the reduced FOV techniques can show better capability to reduce distortions compared to the Full FOV techniques. The rFOV-PS-EPI method can provide DTI images of the phantom at the level of the hardware whereas the conventional rFOV-SS-EPI is useful only when the metal is approximately 20 mm away. In addition, compared to the rFOV-SS-EPI technique, the suggested approach produced smaller signal voids area as well as significantly reduced geometric distortion in Circularity (e.g., p<0.005) and Eccentricity (e.g., p<0.005) measurements. In some implementations, no statistically significant differences can be found for these geometric distortion measurements between the rFOV-PS-EPI DTI sequence and conventional structural T2 images (e.g., p>0.05). In other words, the combination of rFOV and a phase-segmented acquisition approach can be effective for reducing metal-induced distortions in DTI scan on spinal cord with metal hardware at 3 T.

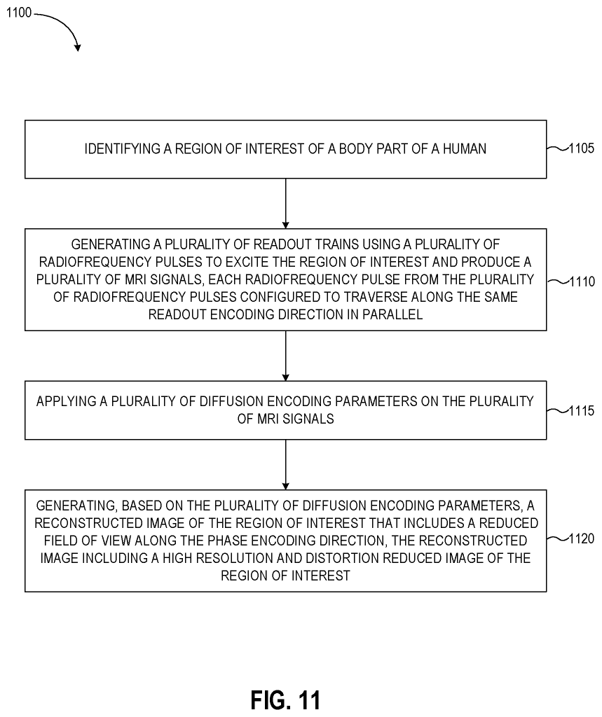

FIG. 11 is a flow diagram of a method 1100 for magnetic resonance diffusion metal artifact correction (DMAC) imaging, according to some embodiments. In some implementations, the method 1100 can be performed by a processor of a compute device or scanner (e.g., MRI scanner). At 1105, the method 1100 includes identifying a region of interest of a body part of a human. The body part can be, for example, the spine, brain, etc.

At 1110, the method 1000 include generating a plurality of readout trains using a plurality of radiofrequency pulses to excite the region of interest and produce a plurality of MRI signals, each radiofrequency pulse from the plurality of radiofrequency pulses configured to traverse along the same readout encoding (RE) direction in parallel. In some implementations, the plurality of radiofrequency pulses includes a two-dimensional radiofrequency excitation pulse (2DRF). In some implementations, prior to the excitation of the region of interest using the plurality of radiofrequency pulses, the method 1100 can include applying a fat saturation technique to suppress unwanted fat signals.

At 1115, the method includes applying a plurality of diffusion encoding parameters on the plurality of MRI signals. In some implementations, the diffusion encoding parameters include scan time, fat region thickness, FOV, number of slices, thickness of slices, repetition time (TR), echo time, PE direction, spatial resolution, echo spacing, matrix size, phase partial Fourier, read partial Fourier, bandwidth, number of segments, and/or the like.

At 1120, the method 1100 include generating, based on the plurality of diffusion encoding parameters, a reconstructed image of the region of interest that includes a reduced field of view (rFOV) along the phase encoding (PE) direction, the reconstructed image including a high resolution and distortion reduced image of the region of interest. In some implementations, the rFOV includes 45 PE lines with an echo spacing of 0.37 ms. The high resolution and distortion reduced image can be achieved via reduced echo-spacing. In some implementations, the method 1100 can include receiving reference images of the region of interest to address phase variation in postprocessing including in the generating of the reconstructed image. The reference images can include Auto-Calibration Scans (ACS), which include slice-by-slice lines acquired at the center of k-space from the plurality of MRI signals. In some implementations, time efficiency of generating the reconstructed image can be improved via simultaneous multi-slice (SMS) acceleration.

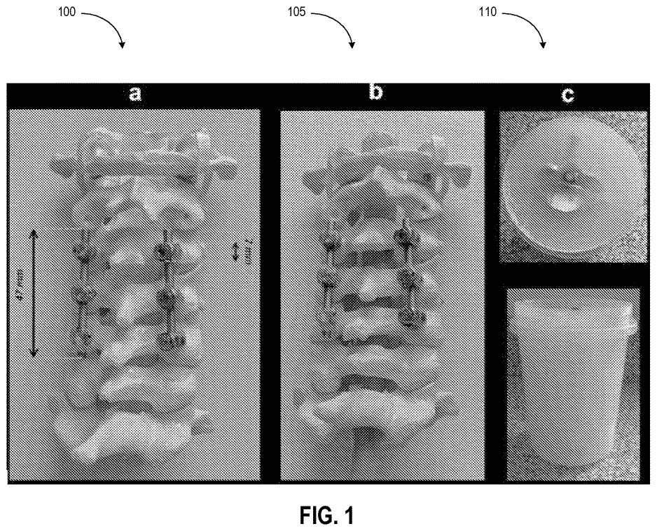

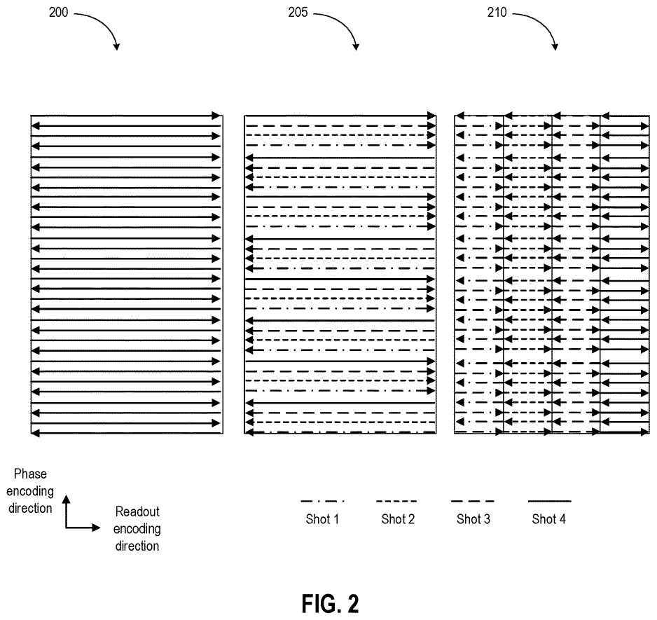

In some implementations, the reconstructed image can be generated via a rFOV-PS-EPI approach and/or the EPI readout sampling scheme as shown in FIG. 2, more specifically, the PS-EPI technique 205 of FIG. 2. For instance, the gold standard SS-EPI technique 200 of FIG. 1 can be modified to build the PS-EPI technique 205 (or PS-EPI MR pulse sequence). Then, the 2DRF excitation pulse can be implemented into the developed PS-EPI sequence to create the rFOV-PS-EPI approach.

### EXAMPLES

### Example 1—Magnetic Resonance Imaging-Metal Artifact Reduction Around Cervical Spine Implant Using Diffusion Tensor Imaging at 3 T

This Example describes the implementation of magnetic resonance imaging to greatly reduce technical challenges, including image distortions, facing the application of DTI in post-surgery cases as well as longitudinal therapeutic and evaluation of the spinal cord. This Example explores a technique based on the combination of the reduced FOV strategy and multi-shot acquisition scheme.

### Materials and Methods

### Protocol Setup

In some implementations, the experiments conducted for the method for magnetic resonance diffusion study can be conducted on 3 T Magnetom Prisma© system with a maximum gradient amplitude of 80 mT/m and a maximum slew-rate of 200 T/m/s. The phantom (e.g., asparagus phantom) can be placed in a vendor 64-channel receive head-neck coil, with the MR body coil used for radiofrequency (RF) transmission.

### Cervical Spine Phantom

FIG. 1 illustrates the spine model as well as the final phantom used in the experiments. In some embodiments, a cervical spine model 100 with MRI compatible Titanium Alloy implants can be used. For instance, ten grams of agar-agar powder was diluted in one liter of water to the phantom was suspended in this solution. An asparagus stalk can be used as a surrogate spinal cord to provide an anisotropic structure to contrast with the surrounding gel medium. It can be placed in the spinal canal of the spine model 105. The spinal phantom model can be centered in a cylindric plastic container. After filling the container with the agar solution, it can be left in ambient temperature to set (110).

### Pulse Sequence Design

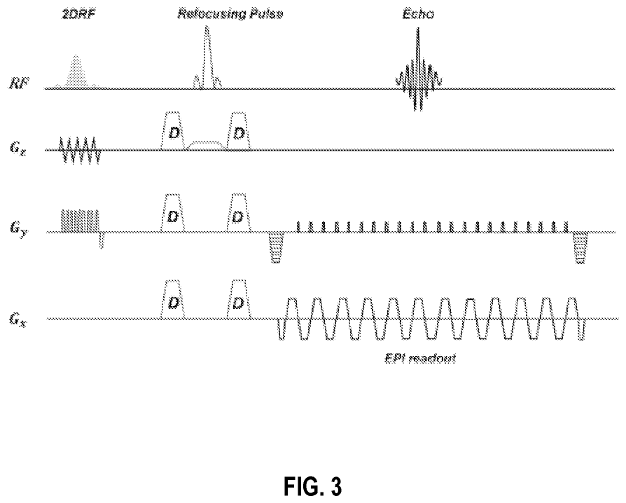

FIG. 2 illustrates the EPI readout sampling scheme of the SS-EPI, PS-EPI, and the RS-EPI. At 200, the gold standard SS-EPI pulse sequence allows collecting the data in one excitation pulse. However, at 205 and 210, the PS-EPI and RS-EPI, respectively, require multiple RF shots for fully sampling the Fourier-Space. In some implementations, the SS-EPI technique can be modified to build the PS-EPI MR pulse sequence using the IDEA pulse sequence environment. Then, the 2DRF excitation pulse can be implemented into the developed PS-EPI sequence to create the proposed rFOV-PS-EPI approach. As illustrated in FIG. 3, the diagram of the rFOV-PS-EPI pulse sequence used for collecting data is displayed. The 2DRF excitation pulse can be used to acquire a rFOV along the Phase Encoding (PE) direction. In some cases, it consists of 45 PE lines with an echo spacing of 0.37 ms, resulting in a total duration of 16.93 ms. The conventional Stejskal-Tanner diffusion preparation scheme with one refusing pulse of 180 degrees can be used to acquire diffusion weighted images. In some cases, although the 2DRF aims to acquire a reduced number of acquired lines at each RF pulse, the Phase segmentation sampling scheme can allow for the achieving of a significantly short EPI readout train, addressing the susceptibility-induced geometric distortions. The fat saturation technique, not shown in the diagram, can be applied prior the RF excitation pulse in order to suppress the unwanted fat signal and address the chemical-shift related artifacts in the images.

TABLE 1
Scan Parameters of diffusion pulse sequences used on Phantom 1
Imaging Parameters used in the Study

| | | | | rFOV-SS- | rFOV-PS- |
|---|---|---|---|---|---|
| Parameters | SS-EPI | PS-EPI | RS-EPI | EPI | EPI |
| TR (ms) | 5200 | 2600 | 5370 | 4500 | 2900 |
| TE (ms) | 90 | 43 | 75 | 62 | 60 |
| Number of slices | 30 | 30 | 30 | 30 | 30 |
| Slice thickness | 5 | 5 | 5 | 5 | 5 |
| (mm) | | | | | |
| FOV (mm²) | 120 × 120 | 120 × 120 | 120 × 120 | 120 × 57 | 120 × 57 |
| Matrix size (mm²) | 134 × 134 | 134 × 134 | 134 × 134 | 134 × 64 | 134 × 64 |
| Spatial resolution | 0.9 × 0.9 × 5 | 0.9 × 0.9 × 5 | 0.9 × 0.9 × 5 | 0.9 × 0.9 × 5 | 0.9 × 0.9 × 5 |
| (mm³) | | | | | |
| PE direction | R > L | R > L | R > L | R > L | R > L |
| Phase Partial | 6/8 | 6/8 | × | 6/8 | 6/8 |
| Fourier | | | | | |
| Read Partial | × | × | 6/8 | × | × |
| Fourier | | | | | |
| Echo spacing (ms) | 1 | 1.11 | 0.38 | 0.98 | 1.1 |
| Bandwidth (Hz/Px) | 1244 | 1382 | 691 | 1166 | 1286 |
| EPI factor | 134 | 19 | 134 | 64 | 8 |
| Number of | 1 | 7 | 7 | 1 | 8 |
| segments | | | | | |
| Fat region | × | × | × | 20 | 20 |
| Thickness (mm) | | | | | |
| Scan Time (min) | 1:13 | 4:36 | 6 | 1:03 | 5:07 |

Twelve axial diffusion-weighted images can be acquired with a b-value of 600 s/mm² applied along twelve non-collinear diffusion encoding directions using the vendor gradient direction file under MDDW diffusion mode. One non-DW image with b-value of 0 s/mm² can be collected prior the dMRI images. The detailed acquisition parameters of all diffusion MR pulse sequences used in this phantom study are shown in Table 1.

In some embodiments, for assessing the effects of the EPI readout length on metal-induced artifacts, one axial image can be collected with the rFOV-PS-EPI at b-value of 0 s/mm² (b0-image) using the following parameters: TR=2900 ms, TE=60 ms, EPI factor=3, number of segments=19, bandwidth=1286 Hz/Pixel, Slice thickness=5 mm, FOV=120×57 mm², matrix size=134×64 mm², number of slices=30, Fat sat region thickness=20 mm, scan time=1:07 minutes. In addition, a conventional anatomical 3D T2-weighted images can be collected using a SPACE pulse sequence. The spatial resolution can be set to 0.9×0.9×5 mm³. The other scan parameters are as fellow: TR=1500 ms, TE=110 ms, Flip angle=120°, bandwidth=620 Hz/Pixel, Slice thickness=5 mm, FOV=120×120 mm², matrix size=128×128 mm², number of slices=30, phase oversampling=30%, slice Partial Fourier=6/8, scan time=1:23 minutes.

### Results

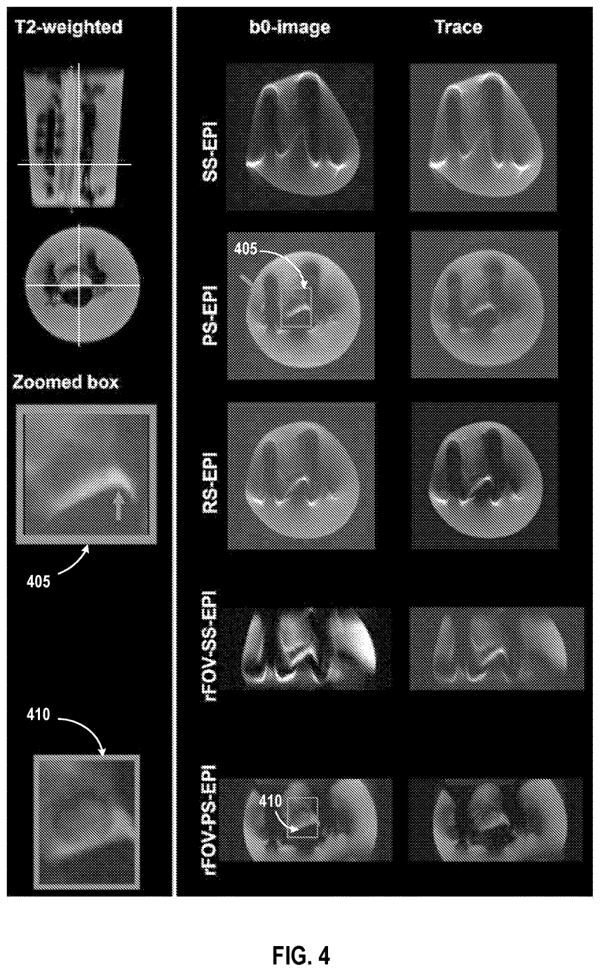

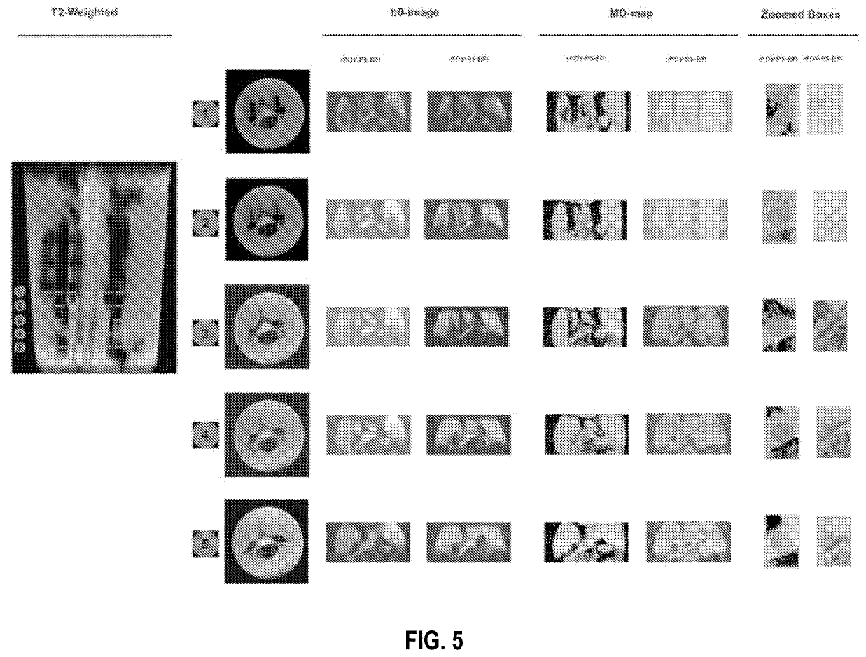

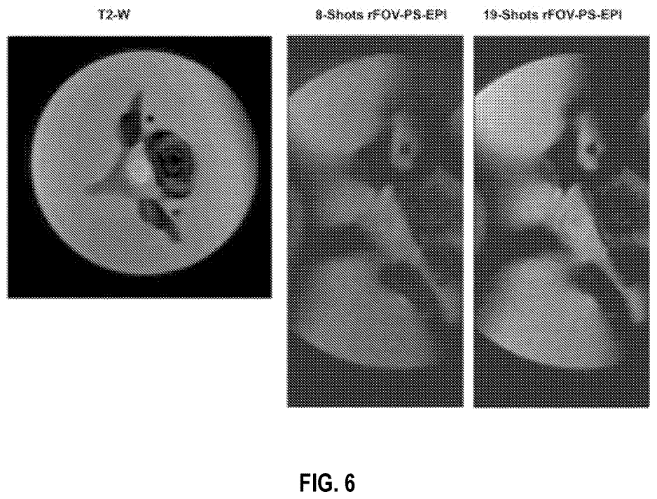

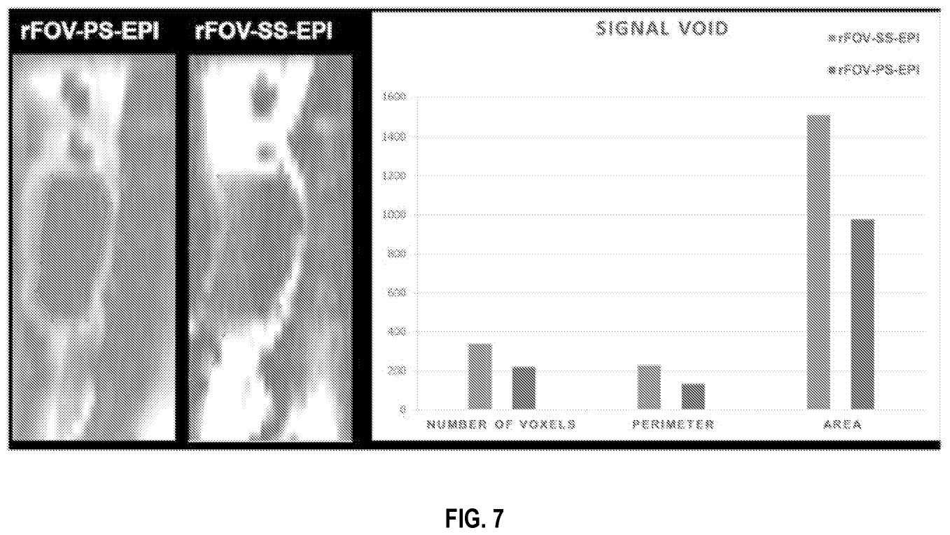

FIG. 4 displays the b0-image and the Trace maps obtained using the standard SS-EPI (top row), the PS-EPI (second row), and the RS-EPI (bottom row) of the same slice shown in the T2-image. The selected slice is located at the metal hardware level and indicated by 410 (cross hair) in the sagittal view of the T2-image. In some instances, the gold standard SS-EPI sequence suffers from severe susceptibility artifacts which affect the shape of the phantom and completely hinders the visibility of the asparagus. The PS-EPI sequence can significantly reduce the geometric distortions compared to the SS-EPI and RS-EPI where the asparagus model is clearly visible as highlighted in the zoomed box 405. However, some residual geometric distortion can be seen as indicated by the red arrows. The fourth and fifth rows of FIG. 4 show the comparison between the rFOV-SS-EPI, commonly used for SC imaging, and the developed rFOV-PS-EPI pulse sequence. The Spinal canal as well as the asparagus cylindrical shape are clearly visible in the images obtained with the proposed rFOV-PS-EPI method (410). In order to accurately assess the potential of suggested method in providing distortion-reduced images near the metal, FIG. 5 compares the b0-images and MD maps obtained at various distances from the metal (metal level, 5, 10, 15, 20 mm, etc.) using the rFOV-PS-EPI and rFOV-SS-EPI pulse sequences. The selected slices are indicated by the dashed colored lines on the sagittal view of the T2-image and displayed on the right. The ability of the developed method to obtain a true shape of the asparagus at b0 and MD maps at a slice level close to the metal implant is highlighted by the colored zoomed boxes. FIG. 6 displays the effects of long echo train EPI readout on the image distortions. Two b0-images acquired with eight-shot and 19-shots. The visual comparison shows no difference in distortions level between the two images. However, the shorter echo train improves the SNR, allowing better detection of small structure such as the asparagus edges.
SNR Measurement: Table 2 shows the slice-by-slice ROI-based SNR values extracted from b0-images collected using the rFOV-SS-EPI and comparison shows that the conventional rFOV-SS-EPI method provide near 20% higher SNR than the proposed rFOV-PS-EPI technique. A t-test comparison also shows a significant difference between the SNR values of the two sequences with a p-value of 0.029 (<0.05).
Signal-void Measurement: The signal-void measurement shows that hypo-signal region around the metal is nearly 30% smaller with the rFOV-PS-EPI with an Area of 976 mm² compared to the rFOV-SS-EPI where the measured Area was 1513 m² (see FIG. 7).
Distortion Evaluation: FIG. 7 displays a direct comparison between the FA and colored FA maps computed from data collected using the rFOV-SS-EPI and rFOV-PS-EPI acquisition methods. Significant reduction in geometric distortions can be seen with data acquired using the proposed technique, allowing a better detection of the asparagus model with its cylindrical shape and the blue color at the colored FA map.

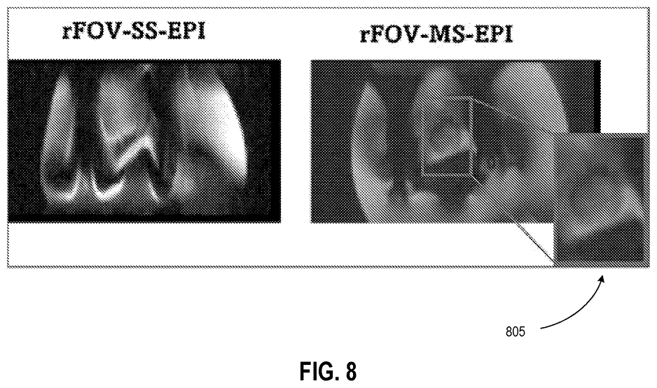

FIG. 8 shows the slice-by-slice comparison of ROI-based parameters:

TABLE 2
SNR measurement extracted using manually selected ROI on b0-images
acquired using the rFOV-SS-EPI and rFOV-PS-EPI pulse sequence

| | rFOV-SS-EPI | | rFOV-PS-EPI | |
|---|---|---|---|---|
| Slice Index | ROI size | SNR | ROI size | SNR |
| 2 | 41 | 57.5 | 41 | 63.11 |
| 3 | 43 | 57.51 | 43 | 61.85 |
| 4 | 40 | 57.49 | 40 | 54.58 |
| 5 | 43 | 57.39 | 43 | 48.92 |
| 6 | 41 | 57.15 | 41 | 51.93 |
| 7 | 22 | 57.51 | 37 | 54.16 |
| 8 | 21 | 57.51 | 37 | 47.51 |
| 9 | 9 | 56.81 | 13 | 39.39 |
| 19 | 13 | 57.21 | 45 | 30.90 |
| 20 | 44 | 42.60 | 44 | 31.08 |
| 21 | 31 | 45.92 | 31 | 25.71 |
| 22 | 27 | 29.38 | 27 | 22.97 |
| 23 | 43 | 36.48 | 43 | 25.09 |
| 24 | 50 | 38.58 | 50 | 31.02 |
| 25 | 34 | 50.42 | 34 | 45.63 |
| 26 | 57 | 56.45 | 57 | 42.03 |
| 27 | 53 | 57.14 | 53 | 48.03 |
| Mean/SD | — | 51.36/13.6 | — | 42.61/12.88 |

Area, Perimeter, Circularity, and Eccentricity extracted from manually drawn ROI on the asparagus phantom. The asparagus cross-section Area measurement illustrates a great similarity between the T2 and the rFOV-PS-EPI values even (SI) near the metal level. In addition, the Perimeter of the selected ROI on the asparagus displays that the rFOV-SS-EPI values are different compared to the T2 and rFOV-PS-EPI due to the geometric distortion. However, the T2 and rFOV-PS-EPI values are similar except for the SI-9 to SI-14 due to the signal dropout induced by the metal. The evaluation of the Circularity of the asparagus using the three pulse sequences demonstrates that the proposed acquisition approach provides better circular-shaped phantom with reduced distortion compared to the standard rFOV-SS-EPI method. The measurement of circularity shows good agreement between the rFOV-PS-EPI and the reference T2 data. The loss of the circularity visible at the SI-9 to SI-18 using the suggested technique is mainly due to the signal void where only a portion of the asparagus is detectable, however the geometric distortion remains low as shown in the top row of FIG. 5. Furthermore, the Eccentricity parameter extracted from the selected ROI shows that the standard acquisition method rFOV-SS-EPI is vulnerable to metal-induced artifacts compared to the reference T2 and the rFOV-PS-EPI imaging techniques. The ROI-based extracted parameters demonstrate that the gold standard imaging technique rFOV-SSEPI is completely hampered by metal artifacts at regions close to the hardware (SI-10 to SI-18), prohibiting carry out any reliable measurements at these slices.

### DISCUSSION

The potential of DTI in pre-operative SCI has been demonstrated in several clinical studies. However, its capability to provide quantitative information of the microstructure on post-surgery SCI cases with metallic hardware remains limited. Severe geometric distortions arise due to the presence of metal in the imaging plane or in the adjacent plane, also known respectively as in-plane and through plane artifacts. It has been shown that the size, the type and the intensity of metal-induced artifacts increase with magnetic field strength and employed pulse sequence parameters such as the echo spacing and the receiver bandwidth. Therefore, a reduced FOV acquisition approach, termed rFOV-PS-EPI, as described herein is designed to mitigate the metal-induced artifacts and to demonstrate the feasibility of performing DTI scans near metallic hardware at ultra-high field strength of 3 T. The b0-images and Trace maps obtained using the standard full FOV pulse sequence (SS-EPI) are dramatically distorted by the susceptibility artifacts (FIG. 4, first row), showing evidence of the vulnerability of this method to the metal-induced distortions and its inappropriacy for postsurgery SCI imaging. The readout segmented (RS-EPI) and phase segmented (PS-EPI) Fourier-space sampling scheme allow achieving shorter echo spacing and high bandwidth per pixel, reducing the severity of image distortions in the presence of metal (FIG. 4). The asparagus shape detected and zoomed in (At 405 of FIG. 4) illustrates that the PS-EPI pulse sequence addresses the geometric distortions compared to SS-EPI and RS-EPI techniques.

In order to achieve a shorter echo-spacing and further improve the image quality, the reduced FOV technique was implemented into the PS-EPI method to create the proposed rFOV-PS-EPI pulse sequence. Despite some signal dropout at the level of the metal implant, the developed method shows great potential in obtaining reduced artifacts and high image quality of the asparagus model compared to the imaging techniques: rFOV-SS-EPI, SS-EPI, PS-EPI, and the RS-EPI.

The efficacy of this technique is demonstrated by a significant reduction of in-plane and through-plane image distortion at 5 mm slice thickness, commonly used in imaging protocols for the spinal cord. The b0-images and MD maps show that using the rFOV-SS-EPI the asparagus shape can be detected only starting from the fifth slice away from the metal (e.g., ~20 mm) which is in line with previous finding. However, it can be partially seen at the level of the spinal hardware and fully visible at the previous slice using the proposed rFOV-PS-EPI method as shown in the red boxes in FIG. 5.

In addition, the validity of the proposed pulse sequence to collect metal reduced DTI images on spinal model with metallic hardware was demonstrated by providing less geometric distortion DTI maps and smaller signal void area around the site of the metal (FIG. 7), providing evidence of its potential for post-operative SCI application to extract information at site of injury. As shown in FIG. 8, The zoomed box 805 highlights the potential of the method described herein to collect distortion-free images at the level of the metal hardware.

The parameters extracted from the selected ROI at each slice on the asparagus cross-section: Perimeter, Area, Circularity, and Eccentricity display great affinity between the rFOV-PS-EPI and the reference T2 metrics, demonstrating the capacity of the proposed approach to collect distortion-free DTI data. In addition, the measurements show that the data collected using the standard imaging method does not allow extracting indices at the site of the metallic implant due to the presence of signal void and severe geometric distortions. Although there was increase in the loss of Circularity and Eccentricity in regions near the metal (SI-9 to SI-19), the rFOV-PS-EPI method provides visualization of a portion of the asparagus with low geometric distortion.

The pairwise comparison between the T2 vs rFOV-SS-EPI and the rFOV-SS-EPI vs rFOV-PS-EPI Circularity and Eccentricity parameters can result in a significant difference (e.g., p-value<0.05). In addition, the cross-section area parameter is significantly different at T2 data when it is compared to ADC maps extracted from rFOV-SS-EPI and rFOV-PS-EPI data. This is mainly due to distortion induced by the high-intensity diffusion gradients.

Although the capability of the developed imaging approach in addressing the metal-induced artifacts for DTI scans around the metallic implant, there remain technical limitations that should be highlighted. The ROI-based SNR comparison at b0-images shows that the rFOV-SSEPI provides significantly better SNR efficiency compared to the proposed rFOV-PS-EPI method with p-value of 0.029 (Table 2), demonstrating the validity of the rFOV-SS-EPI method for pre-operative spinal cord DTI. In addition, several studies have demonstrated that the multishot acquisition strategy is a reliable approach for high-resolution DTI, although it has high-sensitivity to motion-induced artifacts. The Inter-shot phase variations can be amplified by the high-intensity diffusion gradients, resulting in severe ghosting artifacts. Multiples correction strategies, including navigator-based sequences, have been considered for ghosting artifact correction.

In some embodiments, high angular-resolution DTI as well as advanced diffusion models, such as Diffusion Kurtosis Imaging (DKI) and Neurite Orientation Density Dispersion Imaging (NODDI), can be used to fully characterize the SC microstructure enables thorough SC post-operative assessment, albeit an extended acquisition time. In some cases, acceleration acquisition techniques such as the Simultaneous Multi-Slice must be implemented for reducing the scan time for clinical applications.

Additional correction techniques such as View-Angle-Tilting (VAT) or Slice Encoding for Metal Artifact Correction (SEMAC) can be implemented into the proposed pulse sequence for improving the capacity of the in-plane and through slices metal artifacts suppression, providing better measurement of DTI metrics at the site of injury.

### Conclusion

While the reduced FOV (rFOV-SS-EPI) acquisition technique has been conventionally used to perform high resolution DTI on SC, its efficacy for post-operative SCI evaluation remains limited by the presence of artifacts due to metal implants. Here, a technique based on the combination of the reduced FOV strategy and multi-shot acquisition scheme is discussed. The phantom-based results demonstrate the benefit of the proposed acquisition method in achieving high-resolution DTI with reduced geometric distortion near the metal based spinal hardware at 3 T. The validity of the methods described herein to collect metal reduced DTI images on spinal model and SCI patient with metallic hardware is demonstrated by providing less geometric distortion DTI maps and smaller signal void area around the site of the metal at 3 T, allowing extract quantitative measurement at the site of injury. In some embodiments, future work can involve validation of this sequence in post-operative patients with metal implants as well as optimizations to address the remaining technical limitations.

### Example 2—Sequence Description-Distortion-free Multi-shell Diffusion Tensor Imaging (DTI) on In-vivo Human Spinal Cord (SC) with Metallic Implant

This Example describes the implementation of magnetic resonance imaging that demonstrate the feasibility of performing distortion-free multi-shell diffusion Tensor imaging (DTI) on in-vivo human spinal cord (SC) with metallic implant.

In this context, the currently used reduced Field-Of-View Single-Shot Echo Planar Imaging (rFOV-SS-EPI) technique for spinal cord imaging was redesigned to develop the new Phase-Segmented (rFOV-PS-EPI) MR pulse sequence using the IDEA pulse sequence environment (Siemens Healthineers©). The goal of this pulse sequence is to be able to generate distortion free high-resolution diffusion images of the spinal cord as well as brain diffusion. This can allow for accurate measurements and quantification of the diffusion imaging biomarkers that can describe the spinal cord microstructure and integrity in various diseases. In the brain this can generate distortion free tractography images in Parkinson's patients with deep brain stimulator electrodes.

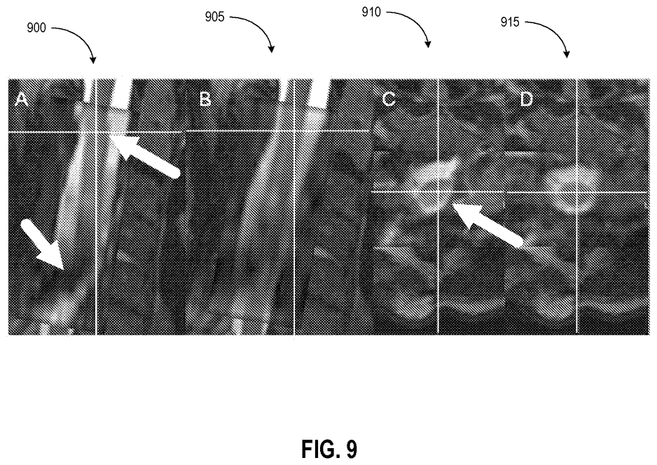

The pulse sequence as described herein can be tested on agar based cervical spine asparagus model installed with commonly used titanium alloy plates and screws. As such, the validity of the proposed approach to collect distortion freed DWI images on spinal model with metallic hardware can be demonstrated. Diffusion tensor imaging showing less geometric distortion on DWI maps and smaller signal void area around the site of the metal on a 3 T MRI scanner can allow for the extraction of reliable quantitative diffusion measures at the site of injury. FIG. 9 shows a preliminary result obtained on one SC Injury patient with metal implant located at C4-C6 scanned with the standard and the proposed acquisition method. Severe distortion of the FA map throughout the SC (arrows) as well as severe loss of signal is seen in C5-C6 region. The FA map overlay on T2-weighted image in an SCI subject using the conventional rFOV-SS-EPI sequence is shown at 900. The same image obtained with the proposed rFOV-PS-EPI sequence showing reduced distortion as well as lower signal loss is shown at 905. At 910 and 915, Axial images using rFOV-SS-EPI and rFOV-PS-EPI respectively showing severe distortion/deformation in 910 is shown.

In some embodiments, the capability of the DMAC pulse sequence can be improved to address three issues. 1. Phase variations induced due to various types of motion; 2. Improvement in image acquisition time to make it clinically feasible; and 3. Incorporating View Angle Tilting (VAT) to further address the metal distortion in-plane.

### Phase Variation Correction

In some cases, the multi-shot EPI (MS-EPI) has the capability and potential in achieving high resolution distortion-reduced diffusion tensor imaging (DTI) of the brain. However, the acquisition of multiple EPI segments for fully sampling the k-space in the presence of subject motion (Respiration, Heart beating, CSF fluid pulsation . . . etc.) induces inter-shot phase error in the final reconstructed image. The phase variation can be amplified by the high-amplitude diffusion-sensitizing gradient pulse, resulting in high-intensity motion/ghosting artifacts. Several correction and acquisition methods have been proposed to address the ghosting artifact, including navigator-based acquisition methods. In some embodiments, the use of navigator-free acquisition strategy can be used to collect reference images (Auto-Calibration Scan (ACS)) prior to the imaging data to address the phase variation in postprocessing. The ACS data consists of slice-by-slice lines acquired at the center of the k-space. The phase maps can be derived from reference data to estimate the inter-shot phase variation and apply phase correction.

### Strategy for Reducing the Scan Time

The major drawback of the multi-shot acquisition technique is the prolonged scan time required to loop over the shots to fully sampling the K-space. To address this issue, Simultaneous Multi-slice (SMS) acceleration approaches will be implemented in the sequence to significantly improve the time efficiency of the sequence. Unlike the standard imaging technique where only a single imaging slice is acquired, SMS enables the concurrent acquisition of several slices during a single diffusion encoding. SMS allows for proportional reductions in total scan time as the multiband factor is increased.

### Implementation of View-Angle Tilting (VAT) Technique:

Although the current implantation has shown a great potential in reducing the metal-induced distortion on DTI data, its application for all post-operative patients with huge amount of metal-based implant remains inefficient. Therefore, metal correction technique such as View-angle Tilting (VAT) will be implemented into the proposed pulse sequence for improving the capacity of metal-induced artifacts suppression, providing better measurement of DWI metrics at the site of injury.

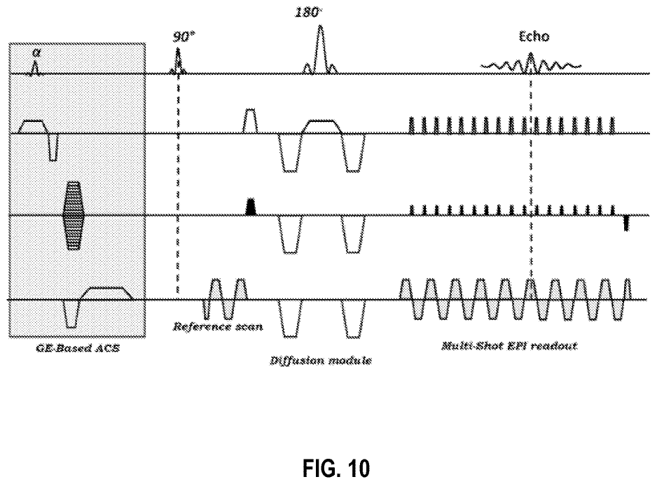

The in-plane signal displacement induced by the susceptibility artifact can be fully compensated by tilting the selected imaging slice at a specific angle. Therefore, an additional gradient pulse is applied along the slice selection axis during the signal readout. The final pulse sequence diagram incorporating VAT technique and ACS scan is shown in FIG. 10. As shown in FIG. 10, the variable angle tilting (VAT) gradient blips can be applied along the slice selection direction at the same time as the phase encoding gradient blips.

### EQUIVALENTS

Although preferred embodiments of the invention have been described using specific terms, such description is for illustrative purposes only, and it is to be understood that changes and variations may be made without departing from the spirit or scope of the following claims.

1. A non-transitory, processor-readable medium storing instructions that executed by a processor, cause the processor to:
identify a region of interest of a body part of a human;
generate a plurality of readout trains using a plurality of radiofrequency pulses to excite the region of interest and produce a plurality of magnetic resonance imaging (MRI) signals, each radiofrequency pulse from the plurality of radiofrequency pulses configured to traverse along the same readout encoding (RE) direction in parallel;
apply a plurality of diffusion encoding parameters on the plurality of MRI signals; and
generate, based on the plurality of diffusion encoding parameters, a reconstructed image of the region of interest that includes a reduced field of view (rFOV) along the phase encoding (PE) direction, the reconstructed image including a high resolution and distortion reduced image of the region of interest.

2. The non-transitory, processor-readable medium of claim 1, wherein the instructions are executed from a magnetic resonance imaging (MRI) scanner.

3. The non-transitory, processor-readable medium of claim 1, wherein the plurality of radiofrequency pulses includes a two-dimensional radiofrequency excitation pulse (2DRF).

4. The non-transitory, processor-readable medium of claim 1, wherein prior to the excitation of the region of interest using the plurality of radiofrequency pulses, the processor is further caused to apply a fat saturation technique to suppress unwanted fat signals.

5. The non-transitory, processor-readable medium of claim 1, wherein the rFOV includes 45 PE lines with an echo spacing of 0.37 ms.

6. The non-transitory, processor-readable medium of claim 1, wherein the diffusion encoding parameters include scan time, fat region thickness, FOV, number of slices, thickness of slices, repetition time (TR), echo time, PE direction, spatial resolution, echo spacing, matrix size, phase partial Fourier, read partial Fourier, bandwidth, or number of segments.

7. The non-transitory, processor-readable medium of claim 1, wherein the reconstructed image including the high resolution and distortion reduced image is achieved via reduced echo-spacing.

8. The non-transitory, processor-readable medium of claim 1, wherein the processor is further configured to receive reference images of the region of interest to address phase variation in postprocessing including in the generating of the reconstructed image.

9. The non-transitory, processor-readable medium of claim 8, wherein the reference images include Auto-Calibration Scans (ACS), the ACSs including slice-by-slice lines acquired at the center of k-space from the plurality of MRI signals.

10. The non-transitory, processor-readable medium of claim 1, wherein time efficiency of generating the reconstructed image is improved via simultaneous multi-slice (SMS) acceleration.

11. A method of a sampling scheme for magnetic resonance diffusion metal artifact correction (DMAC) imaging, the method comprising:
identifying a region of interest of a body part of a human;
generating a plurality of readout trains using a plurality of radiofrequency pulses to excite the region of interest and produce a plurality of magnetic resonance imaging (MRI) signals, each radiofrequency pulse from the plurality of radiofrequency pulses configured to traverse along the same readout encoding (RE) direction in parallel;
applying a plurality of diffusion encoding parameters on the plurality of MRI signals; and
generating, based on the plurality of diffusion encoding parameters, a reconstructed image of the region of interest that includes a reduced field of view (rFOV) along the phase encoding (PE) direction, the reconstructed image including a high resolution and distortion reduced image of the region of interest.

12. The method of claim 11, wherein the method is performed by a magnetic resonance imaging (MRI) scanner.

13. The method of claim 11, wherein the plurality of radiofrequency pulses includes a two-dimensional radiofrequency excitation pulse (2DRF).

14. The method of claim 1, wherein prior to the excitation of the region of interest using the plurality of radiofrequency pulses, the method further includes applying a fat saturation technique to suppress unwanted fat signals.

15. The method of claim 11, wherein the rFOV includes 45 PE lines with an echo spacing of 0.37 ms.

16. The method of claim 11, wherein the diffusion encoding parameters include scan time, fat region thickness, FOV, number of slices, thickness of slices, repetition time (TR), echo time, PE direction, spatial resolution, echo spacing, matrix size, phase partial Fourier, read partial Fourier, bandwidth, or number of segments.

17. The method of claim 11, wherein the reconstructed image including the high resolution and distortion reduced image is achieved via reduced echo-spacing.

18. The method of claim 11, wherein the method further includes receiving reference images of the region of interest to address phase variation in postprocessing including in the generating of the reconstructed image.

19. The method of claim 18, wherein the reference images include Auto-Calibration Scans (ACS), the ACSs including slice-by-slice lines acquired at the center of k-space from the plurality of MRI signals.

20. The method of claim 11, wherein time efficiency of generating the reconstructed image is improved via simultaneous multi-slice (SMS) acceleration.
